(19) United States
(12) Patent Application Publication
(10) Pub. No.: US 2025/0185520 A1
(43) Pub. Date: Jun. 5, 2025

(54) Josephson Junction Device and Method of Producing the Device

(71) Applicant: IMEC VZW, Leuven (BE)

(72) Inventors: Anna Herr, Ellicot City, MD (US); Daniel Perez Lozano, Schaerbeek (BE); Xiaoyu Piao, Heverlee (BE); Zsolt Tokei, Leuven (BE)

(21) Appl. No.: 18/971,628

(22) Filed: Dec. 6, 2024

(30) Foreign Application Priority Data
Nov. 30, 2023 (EP) 23213425.4

(51) Int. Cl. H10N 60/80; H10N 60/01; H10N 60/12; H10N 60/85

(52) U.S. Cl. CPC H10N 60/805; H10N 60/0912; H10N 60/12; H10N 60/85

(57) ABSTRACT

A Josephson junction stack is produced including a first superconducting electrode layer, a barrier layer directly on the first superconducting electrode layer and a second superconducting electrode layer directly on the barrier layer. The superconducting electrode layers are formed of a superconducting nitride material, and the barrier layer consists of a stack of an amorphous Si layer and directly on said amorphous Si layer: a passivation layer formed of a mixture of Si with a second element configured to prevent the formation of silicon nitride during or after the deposition of the second element on a layer of amorphous silicon. The Josephson junction device is produced by patterning the stack.

### CROSS-REFERENCE TO RELATED APPLICATIONS

The present application is a non-provisional patent application claiming priority to European Patent Application No. 23213425.4, filed on Nov. 30, 2023, the contents of which are hereby incorporated by reference.

### FIELD OF THE DISCLOSURE

The present disclosure is related to a Josephson junction device applicable in a superconducting digital logic circuit.

### BACKGROUND

Superconducting digital logic (SDL) is one of the main technologies of interest for overcoming inherent limitations in terms of energy efficiency of CMOS based integrated circuits. An SDL circuit comprises superconducting wires and Josephson junctions. Josephson junctions are known in various forms, but in SDL circuits, the most common implementation takes the form of a dielectric material sandwiched between two superconducting electrodes. In an SDL circuit, the Josephson junction enables changing the magnetic flux in a superconducting loop by an integer number of a single magnetic flux quantum (SFQ).

The material of choice for the electrodes of Josephson junctions applied in SDL circuits has most often been niobium, with Al₂O₃ or amorphous silicon (hereafter abbreviated as α-Si) as the barrier layer. A Nb/α-Si/Nb stack is however not compatible with process steps which require temperatures higher than 150° C.-200° C., such as many steps required in back end of line processing, because the Nb intermixes with silicon above this temperature, thereby reducing the thickness of the barrier. This makes it difficult also to scale down Josephson junctions of this type to the micrometer-sized dimensions required for high density SDL circuits.

### SUMMARY

The present disclosure is related to a Josephson junction stack and a device obtainable from said stack and a method for producing said stack and said device in accordance with the appended claims. A Josephson junction stack according to the present disclosure comprises a first superconducting electrode layer, a barrier layer directly on the first superconducting electrode layer and a second superconducting electrode layer directly on the barrier layer. The superconducting electrode layers are formed of a superconducting nitride material, and the barrier layer consists of a stack of an amorphous Si layer and directly on said amorphous Si layer: a passivation layer formed of a mixture of Si with a second element. The mixed layer is a passivation layer in the sense that it prevents the formation of silicon nitride during or after the formation of the second electrode layer, i.e. it prevents N from the second electrode layer material from reacting with Si from the amorphous Si layer. The mixed layer can thus be said to passivate the α-Si layer.

The present disclosure is in particular related to a Josephson junction stack comprising a first superconducting electrode layer, a barrier layer directly on the first superconducting electrode layer and a second superconducting electrode layer directly on the barrier layer, characterized in that:
the superconducting electrode layers are formed of a superconducting nitride material,
the barrier layer consists of a stack of an amorphous Si layer directly on the first superconducting electrode layer and directly on said amorphous Si layer: a passivation layer formed of a mixture of Si with a second element.

According to an embodiment, the electrode layers are formed of NbTiN or NbN or TiN.

According to an embodiment, the second element is chosen from the group consisting of Ti, Ta and Co.

The present disclosure is also related to a Josephson junction device including a Josephson junction stack according to example embodiments.

The present disclosure is also related to a method for producing a Josephson junction stack according to example embodiments, comprising the steps of:
providing a support substrate,
producing the first electrode layer on the support substrate,
producing an amorphous Si layer on the first electrode layer,
depositing the second element on the amorphous Si layer under conditions which cause intermixing of the second element with a top portion of the amorphous Si layer, so that the original amorphous Si layer is thinned and so that said layer formed of a mixture of Si with the second element is formed on the thinned amorphous Si layer,
producing the second electrode layer on the layer formed of said mixture.

According to an embodiment of the method, the first and second electrode layer are formed of NbTiN and wherein said electrode layers are formed by physical vapor deposition (PVD) at a temperature between 300° C. and 450° C.

According to a further embodiment of the method, the second element is Ti, and wherein the layer of Ti is deposited by PVD at a temperature between 300° C. and 450° C.

According to a further embodiment of the method, the amorphous Si layer is produced by PVD at a temperature between room temperature and 90° C.

The present disclosure is also related to a method for producing a Josephson junction device integrated in a superconducting digital circuit, comprising the steps of:
producing a Josephson junction stack according to example methods,
patterning the stack, to thereby obtain the Josephson junction device, comprising a first and second electrode and a barrier sandwiched between said electrodes,
producing conductors of the circuit, wherein two of said conductors are respectively connected to the first and second electrode of the device.

### BRIEF DESCRIPTION OF THE DRAWINGS

The above described aspects and implementations are explained in the following description of embodiments with respect to the enclosed drawings.

FIG. 1 illustrates a method step for obtaining a Josephson junction stack in accordance with example embodiments.

FIG. 2 illustrates a method step for obtaining a Josephson junction stack in accordance with example embodiments.

FIG. 3 illustrates a method step for obtaining a Josephson junction stack in accordance with example embodiments.

FIG. 4 illustrates a method step for obtaining a Josephson junction stack in accordance with example embodiments.

FIG. 5 illustrates a method step for obtaining a Josephson junction stack in accordance with example embodiments.

All the figures are schematic, not necessarily to scale, and generally show parts to elucidate example embodiments, wherein other parts may be omitted or merely suggested.

### DETAILED DESCRIPTION

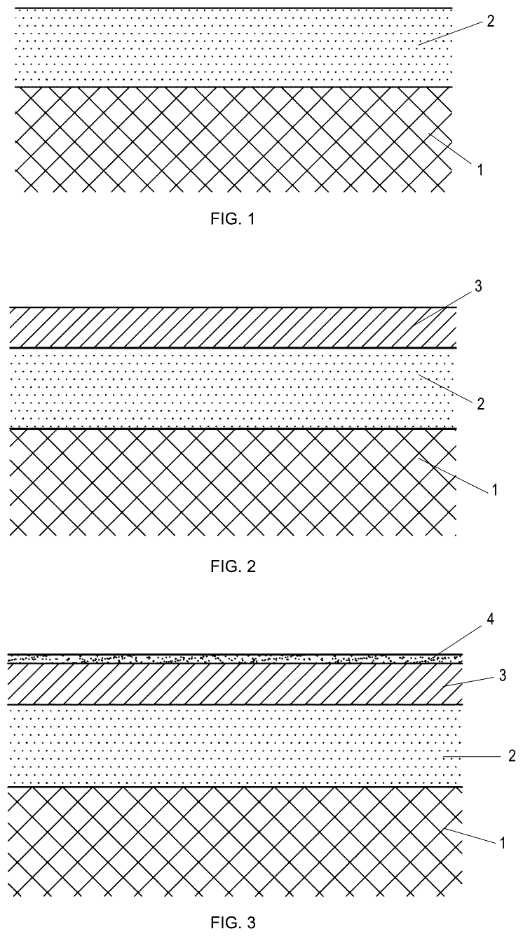

A method for producing a Josephson junction stack according to an embodiment of the present disclosure is described with reference to FIGS. 1 to 5. A Josephson junction stack is defined within the present description as a stack of layers deposited on a substrate and suitable for forming a Josephson junction device by patterning those layers.

Unless it is stated otherwise, the materials cited in the following paragraphs are cited by way of example and these materials therefore do not limit the scope of the present disclosure. All references to dimensions and parameters related to production methods are cited purely by way of example and therefore do not limit the scope of the present disclosure. Alternatives for some of these dimensions, parameters or methods will be mentioned, where appropriate.

FIG. 1 illustrates a small portion of a Si substrate 1 with a SiO₂ layer 2 on the upper surface of the substrate. The Si substrate may be a standard Si process wafer of 300 mm in diameter, or it may be the Si top layer of an SOI (silicon-on-insulator) substrate. Besides Si, the method of the present disclosure is however applicable on other substrate types and materials thereof.

The thickness of the SiO₂ layer 2 is about 100 nm. As shown in FIG. 2, a layer 3 of superconducting NbTiN of about 50 nm thick is deposited on the SiO₂ layer 2. This may be done by various methods known as such in the art. Layer 3 may for example be produced by Physical Vapor Deposition (PVD): with the substrate placed in a PVD chamber, Nb and Ti are co-sputtered at 754 W and 500 W, respectively in the presence of an argon flow of 17 standard cubic centimeters per minute (sccm) and a nitrogen flow of 15 sccm, at a temperature of 420° C. during 40 minutes. It is known to the skilled person that other deposition powers and gas flows can be applied during other deposition times, which results in other superconducting varieties of NbTiN, for example in terms of crystallinity or resistivity.

This is followed, as illustrated in FIG. 3 by the deposition of a layer 4 of α-Si, which can be done also by PVD, at a temperature of 70° C., during about 20 min, resulting in an α-Si layer 4 having a thickness of about 10 nm. The deposition of α-Si takes place after moving the substrate to another PVD reactor, operated at the lower temperature of 70° C.

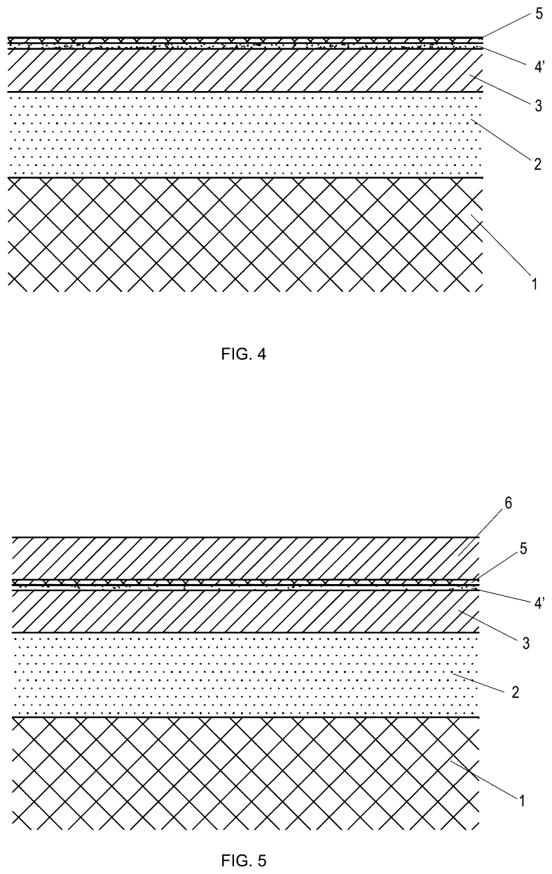

Thereafter, and with reference to FIG. 4, Ti is deposited by PVD on the α-Si layer 4, also at 420° C. (preferably again in the first chamber), during about 200 s. During this deposition, Ti and Si intermix and form a mixed Ti/Si layer 5 on a thinned α-Si layer 4′. The original α-Si layer 4 is thinned as a consequence of the intermixing of Si from the original α-Si layer 4 with the deposited Ti. The thickness reduction of the original α-Si layer is in the order of 5 nm, leaving an α-Si layer 4′ of about 5 nm thick, while the mixed Ti/Si layer 5 has a thickness of about 5 nm. With reference to FIG. 5, this is followed by the formation of a top NbTiN layer 6 of about the same thickness as the first NbTiN layer 3, again by co-sputtering Ti and Nb, for example applying the same parameters as applied for layer 3.

The function of the intermixed Ti/Si layer 5 is to act as a passivation layer that passivates the α-Si layer 4′, i.e. it prevents the formation of SiN by a bonding reaction between Si from the α-Si layer 4′ and N from the second electrode layer 6. Such SiN formation would lead to a much higher resistance of the Josephson junction, and thereby to a reduction of the critical current density of the junction.

The resulting stack is a Josephson junction stack having a bottom electrode layer 3, a top electrode layer 6, an α-Si layer 4′ on the bottom electrode layer and an intermixed Ti/Si passivation layer 5 on the α-Si layer, wherein the α-Si layer 4′ and the intermixed Si/Ti layer 5 together form the barrier of the Josephson junction defined by the stack.

The use of superconducting NbTiN for the electrode layers 3 and 6 is advantageous compared to Nb because the Nb is bound to Ti and N and therefore cannot diffuse into the Si of layer 4. In addition, NbTiN is compatible with high processing temperatures applicable in BEOL processing, so that a Josephson junction device according to the present disclosure can be integrated in a BEOL structure. The deposition of NbTiN takes place at temperatures which are of the same order as the BEOL processing temperatures (preferably between 300° C. and 450° C.). For this reason, the material is compatible with said BEOL processing temperatures, i.e. diffusion of Nb is avoided.

Generally, the deposition temperature of Ti for forming the mixed layer 5 is preferably between 300° C. and 450° C. As stated, the thicknesses of the layers described above are not limiting the scope of the present disclosure. Thicknesses are applicable which enable the functionality of the various layers, namely for layers 3 and 6 to act as electrodes of a Josephson junction device, for layers 4 and 5′ combined to act as barrier layer of said device, and for layer 5′ to act as a passivation layer as explained above.

The Josephson junction stack illustrated in the drawings is produced on a SiO₂ layer 2 which isolates the stack from the Si substrate 1. This is required only if the Si substrate is a standard 300 mm Si wafer with low resistivity. When the Si wafer is a high resistivity wafer, the isolation layer 2 may be omitted. The stack can also be produced after first forming multiple other layers on the Si wafer including front end of line layers and back end of line layers as defined by a particular layout of an SDL circuit.

The temperature resistance of a Josephson junction stack according to the present disclosure combines with other advantages. The junction stack is highly scalable, i.e. it can be processed to form very small devices with good electrical properties in terms of the functionality of the devices in an SDL circuit. The critical current density scales exponentially as a function of the barrier thickness. This means that a required critical current is obtainable in a heavily scaled-down device, while still enabling a relatively thick α-Si barrier 4′ of for example about 10 nm. This is advantageous both for the reproducibility of the junction and for the operation speed: the high barrier thickness leads to a low capacitance, which increases the obtainable speed.

Whereas the present disclosure is limited to the use of amorphous Si in the barrier, other components of the junction are not limited to the above-named materials. The electrode layers 3 and 6 are generally formed of a superconducting material comprising nitrogen. An alternative to NbTiN is for example NbN or TiN.

Other elements instead of Ti may be used for the same function, namely obstructing the formation of SiN by forming a mixed layer formed of said element and Si between the α-Si layer 4′ and the second superconducting electrode layer 6. Such elements include for example Ta and Co.

As to the method of the present disclosure for forming the Josephson junction stack, other processes can be used for forming the layers of the stack. For example Atomic Layer Deposition can be used to form the electrode layers 3 and 6, the α-Si layer 4 and the Ti layer 5. Other suitable methods for forming the bottom and top electrode layers 3 and 6 include single target PVD and CVD (chemical vapor deposition).

An actual Josephson junction device according to the present disclosure, integrated in a layer structure of an integrated circuit chip, can be produced by methods applied for the production of currently known chips comprising SDL circuits. This includes producing a Josephson junction stack in accordance with the present disclosure, and patterning the stack so as to obtain the Josephson junction device comprising a patterned portion of the bottom electrode layer 3, the barrier layer 4′+5 and the top electrode layer 6, respectively forming the first electrode, barrier and second electrode of the device. Following this, conductors are produced wherein two of said conductors are respectively connected to the first and second electrode of the device. An example of a Josephson junction device integrated in an SDL chip is disclosed in patent publication document US20230210022. A Josephson junction stack according to the present disclosure, produced by any of the methods described above, can be used to produce the device as disclosed in the cited application and in other known examples of Josephson junction devices applied in an SDL circuit.

While the present disclosure has been illustrated and described in detail in the drawings and foregoing description, such illustration and description are to be considered illustrative or exemplary and not restrictive. Other variations to the disclosed embodiments can be understood and effected by those skilled in the art in practicing the claimed present disclosure, from a study of the drawings, the disclosure and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

What is claimed is:

1. A Josephson junction stack comprising a first superconducting electrode layer, a barrier layer directly on the first superconducting electrode layer and a second superconducting electrode layer directly on the barrier layer, characterized in that:
the superconducting electrode layers are formed of a superconducting nitride material, and
the barrier layer consists of a stack of an amorphous Si layer directly on the first superconducting electrode layer and directly on said amorphous Si layer: a passivation layer formed of a mixture of Si with a second element.

2. The Josephson junction stack according to claim 1, wherein the second element is chosen from the group consisting of Ti, Ta and Co.

3. The Josephson junction stack according to claim 1, wherein the electrode layers are formed of NbTiN or NbN or TiN.

4. The Josephson junction stack according to claim 3, wherein the second element is chosen from the group consisting of Ti, Ta and Co.

5. A Josephson junction device including the Josephson junction stack according to claim 1.

6. A method for producing a Josephson junction stack according to claim 1, the method comprising:
providing a support substrate;
producing the first electrode layer on the support substrate;
producing an amorphous Si layer on the first electrode layer;
depositing the second element on the amorphous Si layer under conditions which cause intermixing of the second element with a top portion of the amorphous Si layer, so that the original amorphous Si layer is thinned and so that said layer formed of a mixture of Si with the second element is formed on the thinned amorphous Si layer; and
producing the second electrode layer on the layer formed of said mixture.

7. The method according to claim 6, wherein the second element is Ti, and wherein the layer of Ti is deposited by PVD at a temperature between 300° C. and 450° C.

8. The method according to claim 6, wherein the amorphous Si layer is produced by PVD at a temperature between room temperature and 90° C.

9. The method according to claim 6, wherein the first and second electrode layer are formed of NbTiN and wherein said electrode layers are formed by physical vapor deposition (PVD) at a temperature between 300° C. and 450° C.

10. The method according to claim 9, wherein the second element is Ti, and wherein the layer of Ti is deposited by PVD at a temperature between 300° C. and 450° C.

11. The method according to claim 9, wherein the amorphous Si layer is produced by PVD at a temperature between room temperature and 90° C.

12. A method for producing a Josephson junction device integrated in a superconducting digital circuit, the method comprising:
producing a Josephson junction stack according to the method of claim 6;
patterning the stack, to thereby obtain the Josephson junction device, comprising a first and second electrode and a barrier sandwiched between said electrodes; and
producing conductors of the circuit, wherein two of said conductors are respectively connected to the first and second electrode of the device.

13. A method for producing a Josephson junction stack, the method comprising:
providing a support substrate;
producing a first electrode layer on the support substrate;
producing an amorphous Si layer on the first electrode layer;
depositing a second element on the amorphous Si layer under conditions which cause intermixing of the second element with a top portion of the amorphous Si layer, so that the original amorphous Si layer is thinned and so that the layer formed of a mixture of Si with the second element is formed on the thinned amorphous Si layer; and
producing a second electrode layer on the layer formed of said mixture.

14. The method according to claim 13, wherein the second element is Ti, and wherein the layer of Ti is deposited by PVD at a temperature between 300° C. and 450° C.

15. The method according to claim 13, wherein the amorphous Si layer is produced by PVD at a temperature between room temperature and 90° C.

16. The method according to claim 13, wherein the first and second electrode layer are formed of NbTiN and wherein said electrode layers are formed by physical vapor deposition (PVD) at a temperature between 300° C. and 450° C.

17. The method according to claim 16, wherein the second element is Ti, and wherein the layer of Ti is deposited by PVD at a temperature between 300° C. and 450° C.

18. The method according to claim 16, wherein the amorphous Si layer is produced by PVD at a temperature between room temperature and 90° C.

19. A method for producing a Josephson junction device integrated in a superconducting digital circuit, the method comprising:
forming a stack, wherein forming the stack comprises:
providing a support substrate;
producing a first electrode layer on the support substrate;
producing an amorphous Si layer on the first electrode layer;
depositing a second element on the amorphous Si layer under conditions which cause intermixing of the second element with a top portion of the amorphous Si layer, so that the original amorphous Si layer is thinned and so that the layer formed of a mixture of Si with the second element is formed on the thinned amorphous Si layer; and
producing a second electrode layer on the layer formed of said mixture;
patterning the stack, to thereby obtain the Josephson junction device, comprising a first and second electrode and a barrier sandwiched between said electrodes; and
producing conductors of the circuit, wherein two of said conductors are respectively connected to the first and second electrode of the device.

20. The method according to claim 19, comprising at least one of:
wherein the second element is Ti, and wherein the layer of Ti is deposited by PVD at a temperature between 300° C. and 450° C.;
wherein the amorphous Si layer is produced by PVD at a temperature between room temperature and 90° C.; or
wherein the first and second electrode layer are formed of NbTiN and wherein said electrode layers are formed by physical vapor deposition (PVD) at a temperature between 300° C. and 450° C.
